(19) United States
(12) Patent Application Publication
(10) Pub. No.: US 2014/0111205 A1
(43) Pub. Date: Apr. 24, 2014

(54) Method and Device for Holding and Adjusting Permanent Magnets Included in an NMR System

(71) Applicant: Commissariat A L'Energie Atomique Et Aux Energies Alternatives, Paris (FR)

(72) Inventors: Sandrine Cazaux, Montlhery (FR); Alexandre Branco, Fontenay-Sous-Bois (FR)

(73) Assignee: Commissariat A L'Energie Atomique Et Aux Energies Alternatives, Paris (FR)

(21) Appl. No.: 14/059,902

(22) Filed: Oct. 22, 2013

(30) Foreign Application Priority Data
Oct. 23, 2012 (FR) 1260061

(51) Int. Cl. G01R 33/383

(52) U.S. Cl. CPC G01R 33/383
USPC 324/318

(57) ABSTRACT

The device for holding and adjusting individual permanent magnets included in a spectroscopy or a magnetic resonant imaging system comprises, for each individual permanent magnet: a first rigid fork of non-magnetic material that laterally clamps in fixed manner the individual permanent magnet; and a second rigid fork of non-magnetic material that engages the first fork via a slideway system and that is provided with means for radially adjusting the first fork relative to a stationary support to which the second fork is attached. The device enables fine adjustment to be made after assembling a magnetized structure that is constituted by rings of individual magnets.

### CROSS-REFERENCE TO RELATED APPLICATIONS

This application claims priority to French Patent Application No. 1260061, filed Oct. 23, 2012, the disclosure of which is hereby incorporated in its entirety by reference.

### FIELD OF THE INVENTION

The present invention relates to a method and to a device for holding and adjusting permanent magnets included in a system for creating spectra and/or images by nuclear magnetic resonance (NMR).

The invention also relates to a magnetized structure applied to an NMR apparatus performing such a method and to such a device for holding and adjusting permanent magnets.

### PRIOR ART

NMR relies on using magnetic fields, including a “main” magnetic field that must be as uniform as possible in the region under examination or “zone of interest” ZI. Conventionally, the term “homogeneous” is used to designate this uniform nature. This very homogeneous magnetic field is generated by magnets, and nowadays the magnets in most widespread use are constituted by superconducting coils that convey electric currents that generate the field without dissipating energy, providing they are kept at very low temperature. Such a magnet device generally has the outside appearance of a cylindrical tunnel into which an article or a patient for imaging is inserted.

The analysis of anisotropic samples, e.g. solids, by NMR requires the sample to be turned about an axis that is oriented at a so-called “magic” angle (arctan(√2)≈54.7).

Most of the magnets presently used for NMR to create fields that are intense and homogeneous are based on the flow of current in coils. Regardless of whether the coils are resistive or superconducting, it is always necessary to supply the magnet with current and also with cryogenic fluids for superconducting coils. As a result apparatuses are bulky and difficult to move. Resistive coils require major current feeds while superconducting coils involve the use of a cryostat filled with cryogenic liquids, and such a cryostat is difficult to move.

A structure based on permanent magnets makes it possible to avoid those constraints, since the material is magnetized once and forever, and provided it is handled appropriately, it conserves its magnetization without external maintenance. However, permanent magnet materials are of remanence (the magnetization that remains in the material once magnetized) that is limited so generating strong fields in large working zones requires large quantities of material. Since the density of such materials is about 7.5 grams per cubic centimeter (g·cm⁻³), systems quickly become very heavy. It is therefore important to minimize the quantity of material used for a given field.

The difficulty with NMR magnetic systems made of permanent materials lies in the need to couple intense fields with a high degree of homogeneity. Methods of fabricating materials such as NdFeB do not make it possible to guarantee that magnetization is perfectly homogeneous, and they are not perfectly repeatable. Thus, although it is possible to design structures that ought to deliver the desired homogeneity, it is still necessary to make provision for a posteriori adjustment in order to be able to correct for imperfections in the material.

The overall shape of such magnetized structures is generally that of a cylinder in which the structure has at least one axis of symmetry. This makes it possible to overcome numerous factors of inhomogeneity. The zone of interest is then at the center of the cylinder and this zone can be accessed along the axis by providing a hole in the cylinder, or through the side by splitting the cylinder in two.

Proposals have already been made, e.g. in documents WO 2011/023912, WO 2011/023910, and WO 2011/023913, for assemblies of magnetized structures on a common axis for inducing in their center a homogeneous magnetic field of predetermined orientation. Such assemblies are suitable for providing portable NMR at low cost, e.g. for use on small animals or on portions of the body. They can also make it possible to observe zones that are not observable with superconducting medical imaging, in particular boundary zones, e.g. between the brain and the skull.

Nevertheless, such magnetized structures are capable of operating only because of the quality of the permanent magnets and the way in which they are assembled together. It is therefore important to associate them with holding and adjustment possibilities that allow for compensation of geometrical defects in the fabrication of the magnets and of the mechanism, and also of magnetic defects and of temperature gradients. The precision required in a magnetic field for an NMR application is achievable, providing it is possible to make use of such holding and adjustment devices up to a very late stage, including while the magnetized structure is in use.

### DEFINITION AND OBJECT OF THE INVENTION

The present invention seeks to remedy the above-mentioned drawbacks and to make it possible in simplified manner to provide a device for holding and adjusting individual permanent magnets included in a spectroscopy or a magnetic resonant imaging system.

More particularly, the invention seeks to provide a magnetized structure for an NMR apparatus in which it is possible to adjust the position of individual magnets after the magnetized structure has been assembled, so as to guarantee that a homogeneous field is obtained.

The invention also seeks to provide a magnetized structure for an NMR apparatus that is compact, without unbalance, as light as possible, and in which the support devices take up as little space as possible.

In accordance with the invention, these objects are achieved by a device for creating a main magnetic field of a spectroscopy or a magnetic resonant imaging system with individual permanent magnets being held and adjusted for the purpose of creating said magnetic field, said device being included in the spectroscopy or magnetic resonant imaging system, said system presenting a longitudinal axis relative to which a system of cylindrical coordinates can be defined with a longitudinal direction, a radial direction, and a tangential direction, each individual permanent magnet presenting main faces perpendicular to said longitudinal axis and lateral faces perpendicular to said main faces, wherein the device includes, for each individual permanent magnet, a first rigid fork of non-magnetic material that clamps the individual permanent magnet laterally in fixed manner, and a second rigid fork of non-magnetic material that engages said first fork by means of a slideway system oriented along said radial direction and that is provided with radial adjustment means for radially adjusting the first fork relative to a stationary support to which the second fork is attached, and wherein the second rigid fork is also provided with adjustment means for adjustment relative to the stationary support in a direction perpendicular to the main faces of said individual permanent magnet.

In a preferred embodiment, each individual permanent magnet is fastened in the first rigid fork by adhesive bonding.

In a particular embodiment, said radial adjustment means comprise a threaded rod having one end engaged in a notch formed in a rear portion of said first fork.

Advantageously, the stationary support is provided with pegs for positioning the second forks associated with the individual permanent magnets that are arranged in a plurality of layers that are superposed along said longitudinal axis.

All of said stationary supports associated with the various individual permanent magnets are clamped between first and second holder rings.

The individual permanent magnets may be arranged in at least first and second layers that are superposed along said longitudinal axis.

Under such circumstances, each stationary support is associated with a plurality of superposed individual permanent magnets and co-operates with guide grooves or splines formed in or on the second rigid forks respectively associated with said superposed individual permanent magnets.

By way of example, each stationary support may be associated with four superposed individual permanent magnets having their second rigid forks co-operating with adjustment means for adjustment relative to the stationary support in a direction perpendicular to the main faces of said individual permanent magnets, said adjustment means being distributed over two opposite sides of said stationary support.

The first and second rigid forks may be made of 7075 aluminum alloy, for example.

The individual magnets may present a shape selected in particular from rectangular blocks, cylinders, and sectors, e.g. a shape that is substantially trapezoidal.

The invention also provides a magnetized structure applied to a nuclear magnetic resonance apparatus, the structure inducing, in a central zone of interest, a homogeneous magnetic field that is oriented along an axis at the magic angle relative to a longitudinal axis of the structure and comprising first and second magnetized rings arranged symmetrically relative to a plane that is perpendicular to said longitudinal axis and that contains said central zone of interest, and a middle annular magnetized structure interposed between the first and second magnetized rings, likewise arranged symmetrically about said plane, and subdivided into at least two slices along the longitudinal axis, the first and second magnetized rings and the various slices of the middle magnetized structure each being subdivided into individual permanent magnets of sector shape, wherein the sector-shaped individual permanent magnets of the various slices of the middle magnetized structure form parts of a device for creating a main magnetic field as defined above.

More particularly, the individual permanent magnets of the first and second magnetized rings are adhesively bonded to one another in fixed manner, while the magnetized structure includes longitudinal adjustment means between the first and second magnetized rings and the middle annular magnetized structure.

The invention also provides a method of creating a main magnetic field of a spectroscopy or a magnetic resonant imaging system with individual permanent magnets for creating said main magnetic field being held and adjusted, said spectroscopy or magnetic resonant imaging system presenting a longitudinal axis relative to which a system of cylindrical coordinates can be defined with a longitudinal direction, a radial direction, and a tangential direction, each individual permanent magnet presenting main faces perpendicular to said longitudinal axis and lateral faces perpendicular to said main faces, wherein for each individual permanent magnet it comprises the following steps:
placing a first rigid fork of non-magnetic material in fixed manner on each individual permanent magnet, the fork laterally clamping the individual permanent magnet in fixed manner;
for each individual permanent magnet, arranging a second rigid fork of non-magnetic material that engages said first fork via a slideway system oriented along said radial direction; and
radially adjusting the position of the first fork relative to a stationary support to which said second fork is attached; and

wherein it further comprises the step consisting in adjusting the position of the second fork relative to said stationary support in a direction perpendicular to the main faces of said individual permanent magnet.

In a particular embodiment a given stationary support is associated with a plurality of individual permanent magnets that are superposed along said longitudinal axis and fitted with said first and second rigid forks.

### BRIEF DESCRIPTION OF THE DRAWINGS

Other characteristics and advantages of the invention appear from the following description of particular embodiments of the invention given as examples and with reference to the accompanying drawings, in which:

FIG. 1 is a diagrammatic perspective view of an example device of the invention for holding and adjusting a set of superposed individual magnets;

FIG. 2 is a diagrammatic perspective view analogous to FIG. 1, but showing, for one of the individual magnets, a second fork that is disconnected from the first fork secured to the individual magnet;

FIG. 3 is an elevation view of the FIG. 1 device;

FIG. 4 shows the FIG. 1 device in exploded form with a support member separated from the individual magnets and their associated forks;

FIG. 5 is a perspective view showing the outside appearance of a magnetized structure of the invention that is provided with devices for holding and adjusting individual magnets of the kind shown in FIGS. 1 to 4;

FIG. 6 is an elevation view of the FIG. 5 magnetized structure showing the top and bottom magnet rings separated from the intermediate magnet ring, which is provided with devices for holding and adjusting individual magnets;

FIG. 7 is an axial half-section of the FIG. 5 magnetized structure, which is also fitted with a thermal protection enclosure;

FIGS. 8 and 9 are respectively a perspective view and an axial half-section of the bottom magnet ring of the FIG. 5 magnetized structure, shown without the top protection plate;

FIGS. 10 and 11 are respectively an elevation view and a perspective view of an example magnetized structure to which the invention is applicable;

FIG. 12 shows an example of a sector-shaped individual magnet having curved edges;

FIG. 13 shows an example of an individual magnet that is cylindrical in shape; and

FIG. 14 shows an example of an individual magnet that is of rectangular block shape.

### DETAILED DESCRIPTION OF PREFERRED EMBODIMENTS

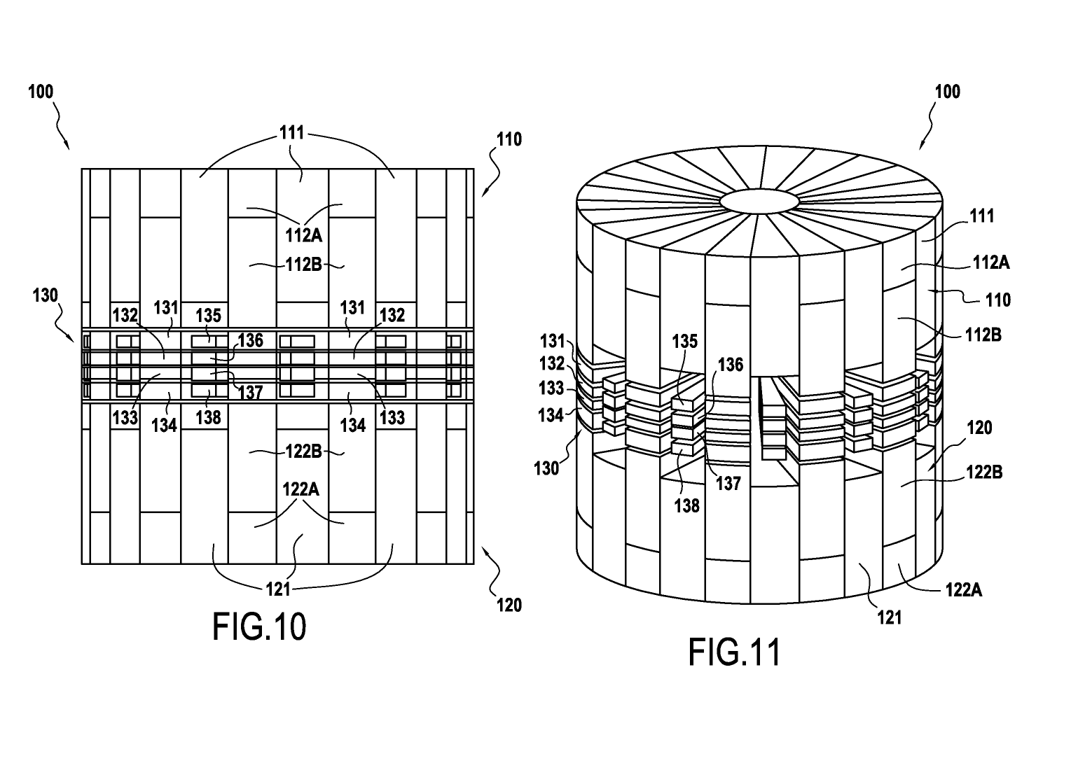

The description begins with reference to FIGS. 10 and 11 of an example magnetized structure applied to a nuclear magnetic resonance apparatus to which the invention is applicable.

In FIGS. 10 and 11, there can be seen a magnetized structure 100 applied to a nuclear magnetic resonance apparatus for inducing a homogeneous magnetic field in a central zone of interest, the field in this example being oriented along an axis extending at the magic angle relative to a longitudinal axis of the structure.

The magnetized structure 100 comprises first and second magnetized rings 110, 120 arranged symmetrically about a plane that is perpendicular to said longitudinal axis and contains the central zone of interest.

A middle annular magnetized structure 130 is interposed between the first and second magnetized rings 110, 120 and is also arranged symmetrically about said plane, and it is subdivided in this example into four slices along the longitudinal axis.

The first and second magnetized rings 110, 120 and the various slices of the middle magnetized structure 130 are all subdivided into individual permanent magnets.

By way of example, the magnetized ring 110 may be magnetized radially relative to the longitudinal axis with diverging magnetization, while the magnetized ring 120 is magnetized radially relative to the longitudinal axis with converging magnetization, the middle magnetized structure 130 being magnetized along the longitudinal axis so as to create a hybrid structure, however the invention is not limited to this particular example and it applies to all kinds of magnetized structures made up of individual permanent magnets.

In general, it is advantageous to make each annular cylindrical structure in the form of a regular polyhedron structure having a set of N identical segments. Each segment is thus a right prism of section substantially in the form of an isosceles trapezoid and its magnetization is parallel to the height of the prism or forms a predetermined angle relative to said height.

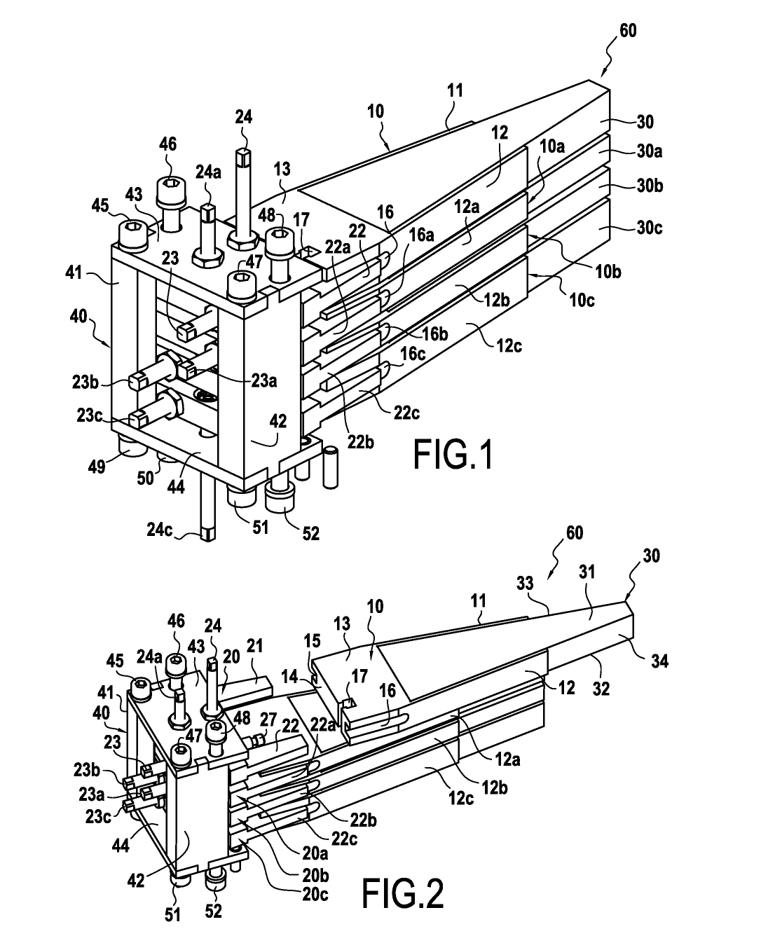

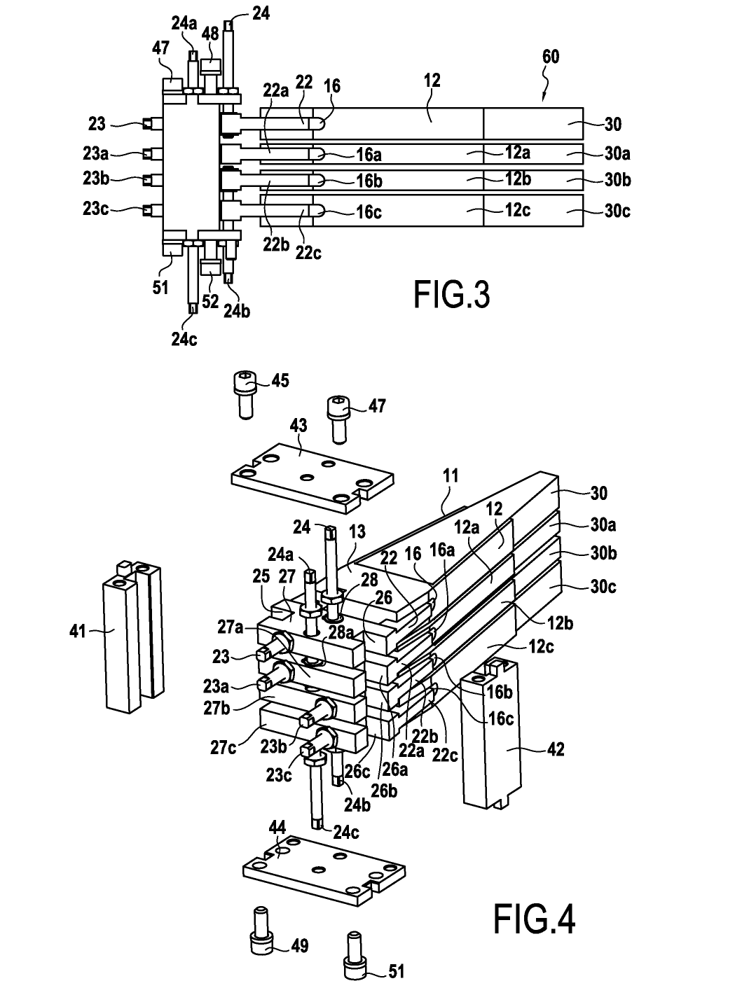

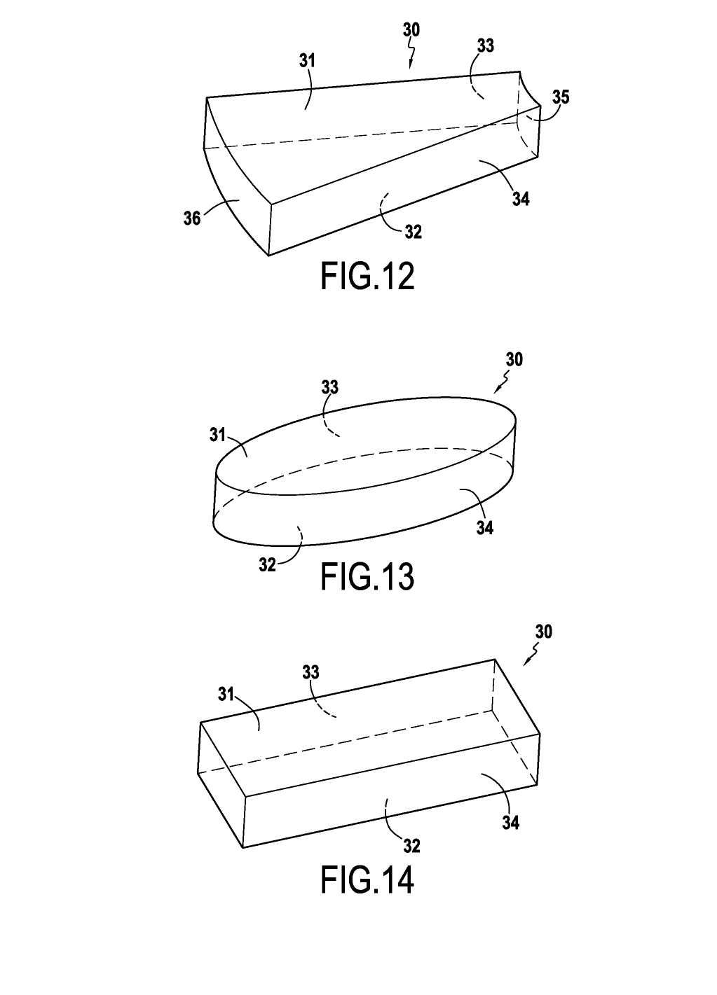

Nevertheless, the invention may be made with numerous variants. Thus, each segment or individual permanent magnet 30 may not only be in the form of an optionally isosceles trapezoid, as shown in particular in FIGS. 1 to 4, but it could also be in the shape of an approximate trapezoid with its substantially parallel sides 35, 36 being curved, as shown in FIG. 12. By way of example, each segment or individual permanent magnet 30 may also be in the shape of a vertical cylinder, e.g. of oval section, as shown in FIG. 13, or it may be in the form of a rectangular block, as shown in FIG. 14.

More particularly, the individual permanent magnets of the first and second magnetized rings 110, 120 are held stationary relative to one another by adhesive, but the magnetized structure includes means for longitudinal adjustment between the first and second magnetized rings 110, 120 and the middle annular magnetized structure 130.

Each individual segment of a slice of the middle magnetized structure 130 is furthermore not contiguous relative to the neighboring segment so as to make it possible to perform mechanical adjustment after assembly.

In the example of FIGS. 10 and 11, each slice of the middle magnetized structure 130 is shown as comprising an alternation of two types of sector-shaped individual magnets. Thus, for the first slice, there is an alternation of non-touching magnets 131 and 135, for the second slice there is an alternation of non-touching magnets 132 and 136, for the third slice there is an alternation of non-touching magnets 133 and 137, and for the fourth slice there is an alternation of non-touching magnets 134 and 138. The magnets 131 to 134 of the various slices are superposed, as are the magnets 135 to 138 of the various slices.

In the example shown in FIGS. 10 and 11, each slice of the middle magnetized structure 130 is shown as having twelve individual magnets of a first type (e.g. 131, 132, 133, or 134) that alternate with twelve individual magnets of a second type (e.g. 135, 136, 137, or 138). Nevertheless, the invention is not limited to these numbers of individual magnets per slice.

Likewise, it would also be possible for the non-touching individual magnets of the slices of the middle ring 130 to be in the form of only the first type of individual magnets 131 to 134 or only the second type of individual magnets 135 to 138, instead of being made up of individual magnets of two different types.

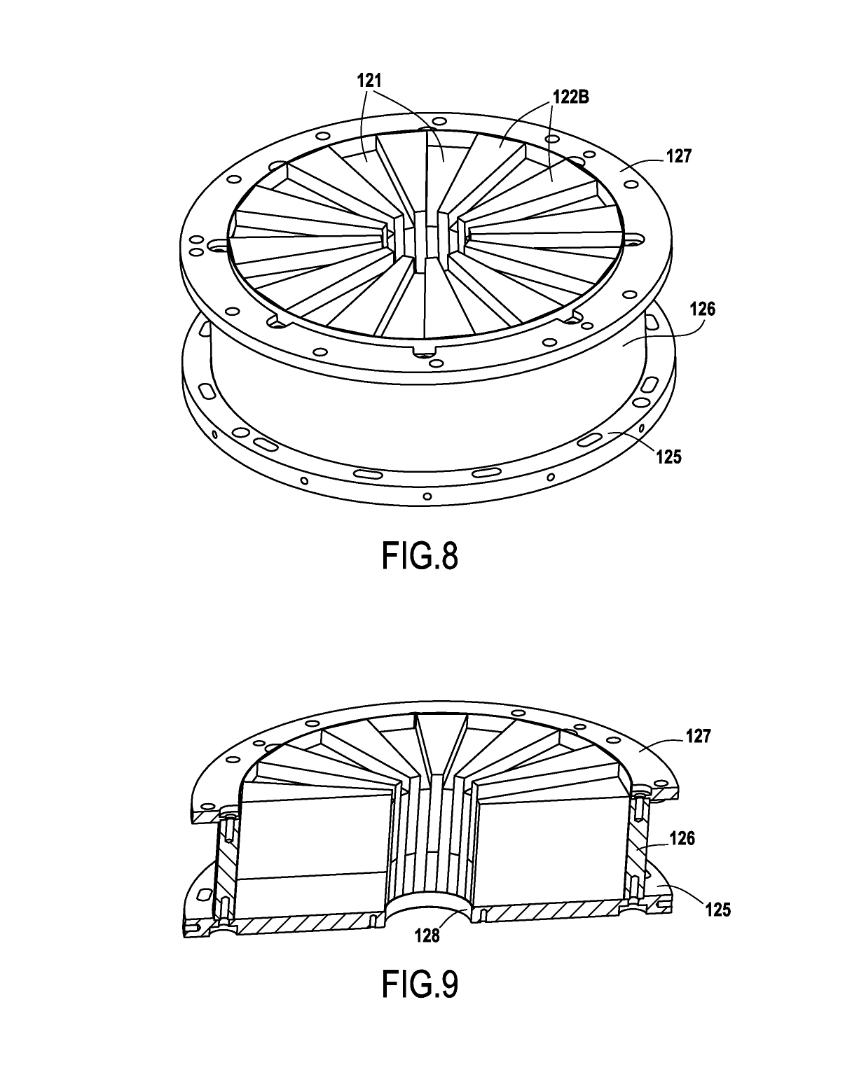

In the example of FIGS. 10 and 11, each of the magnetized rings 110 and 120 has firstly a first series of identical sector-shaped individual magnets 111 or 121 respectively in a regular distribution, and secondly a second series of superposed pairs of identical sector-shaped individual magnets 112A, 112B, or 122A, 122B respectively, that are arranged in interleaved alternation with the individual magnets of the first series 111 or 121 respectively, in touching manner. Furthermore, the individual magnets 111 or 121 respectively are set back a little relative to the contiguous individual magnets 112B or 122B respectively, as can also be seen in FIGS. 8 and 9 in the inside face that faces the middle ring 130. Nevertheless, this merely constitutes one particular embodiment, and this configuration is not limiting.

With reference to FIGS. 1 to 6, there follows a description of an embodiment of the device of the invention suitable for holding in position and adjusting the individual magnets of the central ring 130 in individual and independent manner both radially and vertically, even after the magnetized structure 100 has been assembled.

With reference to FIGS. 1 to 4, and more particularly to FIG. 2, it can be seen that each individual permanent magnet 30 presents main faces 31 and 32 in the form of isosceles trapezoids inscribed in a sector, and two elongate lateral faces 33, 34. For each individual permanent magnet 30 a first rigid fork 10 of non-magnetic material has branches 11, 12 that clamp laterally in fixed manner on the lateral faces 33, 34 of the individual permanent magnets 30. Each individual permanent magnet 30 is held stationary by adhesive in the first rigid fork 10. The first fork 10 that holds the lateral faces 33, 34 of the individual magnets 30 by its plane branches 11, 12 is optimized in order to provide a maximum area of adhesive and thus obtain good mechanical strength. Holding an individual magnet 30 laterally makes it possible to provide a positioning device that is quite compact and that makes it possible to conserve a set of individual magnets that are very close to one another.

It should be observed that NMR devices may exist that use individual magnets of shapes other than the shape shown in FIGS. 1 to 4 and to which the invention is equally applicable.

Thus, as shown in FIG. 12, an individual magnet 30 may be in the form of an approximate trapezoid having two opposite sides 35, 36 that are curved and two lateral sides 33, 34 that are rectilinear.

As shown in FIG. 13, an individual magnet 30 may be in the form of a cylinder placed generally vertically and capable of having a section of arbitrary shape, e.g. oval.

As shown in FIG. 14, an individual magnet 30 may also be in the form of a rectangular block.

It should be observed that with individual magnets 30 that are cylindrical, for example, the stationary clamp 10 may present branches 11, 12 that are not necessarily plane and that may be better adapted to the shape of the individual magnet 30. A stationary clamp 10 may thus present curved branches 11, 12 that are adapted to fit closely against the curved surface 33, 34 of a magnet of cylindrical shape (FIG. 13).

The combination of the first fork 10 with a second fork 20 makes it possible to adjust the position of the magnet radially while using a guide system that is simple and compact and that allows movement to be reversible.

The second rigid fork 20 of non-magnetic material has two arms 21, 22 that engage the body 13 of the first fork 10 via a slideway system. The second fork 20 is also provided with adjustment means 23 for adjusting the radial position of the first fork 10 and of the individual magnet 30 relative to a stationary support 40 in which the second fork 20 is held captive.

More particularly, the first fork 10 has a body 13 to which the plane branches 11, 12 are attached for clamping the magnet 30. The lateral portions of the body 13 of the first fork present grooves 15, 16 (or in a variant splines) for co-operating with complementary elements (splines or grooves) of the branches 21, 22 in order to form said slideways. These slideways enable the magnet 30 to be held securely in spite of the large magnetic forces exerted in all directions. The complementary elements (spline, groove) of the slideways may be made of non-magnetic materials (e.g. bronze, titanium, an aluminum alloy, or an alloy of aluminum and beryllium known under the trademark “Albemet”), in order to limit friction and deformation due to the magnetic forces.

The means 23 for radially adjusting the first fork 10 comprise a threaded rod having one end 27 engaged with a notch 17 formed in a rear portion 14 of the body 13 of the first fork 10.

The holding and adjustment device of the invention is compact and compatible with the small amount of space available between adjacent individual magnets 30 so as to conserve an overall structure that is compact and light in weight. The first and second forks 10, 20 are rigid and made of non-magnetic material (e.g. bronze, titanium, an aluminum alloy, or an alloy of aluminum and beryllium known under the trademark “Albemet”) so as to avoid disturbing the magnetic forces and avoid demagnetizing the permanent magnets 30.

The threaded rod 23 of strong material and of fine pitch makes it possible to achieve radial adjustment that may lie in the range a few micrometers to a few millimeters, for example. The holding and adjustment device of the invention thus constitutes a precision mechanism, while presenting the ruggedness needed to withstand the effects of the magnetic forces that are present, and also, for example, centrifugal force when the magnetized structure is in rotation.

Advantageously, the second rigid fork 20 is also provided with adjustment means 24 for adjusting its position relative to the stationary support 40 in a direction that is perpendicular to the main faces of the individual permanent magnet 30 held by the first fork 10. This adjustment may be permanent, e.g. by using spacers, or variable, e.g. by using threaded rods.

Thus, as can be seen in FIG. 4, notches or grooves 25, 26 are formed on either side of the body 27 of the second fork 20 in order to co-operate with splines formed on the uprights 41, 42 of the stationary support so as to allow the body 27 of the second fork 20 to slide relative to the stationary support 40 in a vertical direction in the configuration shown in FIGS. 1 to 4, when acting on the corresponding threaded rod 24 that serves to control the movement of the second fork 20 relative to the stationary support 40.

The micrometer screw or threaded rod 24 co-operates with a circlip 28 that enables the vertical movement of the second fork 20, and thus of the individual magnet 30, to be reversible. While taking measurements or while the magnetized structure is rotating, adjustment may be blocked merely by means of a nut.

As can be seen in FIGS. 1 to 6, when a middle annular magnetized structure comprises a plurality of superposed layers of individual magnets (e.g. two or four layers), it is possible to use the same stationary support 40 for a set 60 made up of a plurality of superposed individual magnets belonging to different layers and each provided with a first fork 10 and with a second fork 20, as described above.

FIGS. 1 to 4 show four superposed individual magnets 30, 30a, 30b, and 30c that are identical, each of them co-operating with a respective holding and adjustment device comprising a first fork 10, 10a, 10b, or 10c and a second fork 20, 20a, 20b, or 20c. All of the elements of the holding and adjustment device relating to the magnets 30a, 30b, and 30c situated under the magnet 30 are given the same references as the elements of the holding and adjustment device concerning the magnet 30, but with a letter a, b, or c respectively being added thereto, and these elements are not described separately.

The stationary support 40 comprises top and bottom end plates 43 and 44 together with lateral uprights 41, 42 provided with splines or grooves for co-operating with the grooves or splines 25, 26; 25a, 26a; 25b, 26b; 25c, 26c of the superposed second forks 20, 20a, 20b, and 20c. The column-shaped stationary support 40 is provided with positioning pegs 45 to 48 and 49 to 52 that co-operate with the end plates 43 and 44 respectively in order to obtain mechanical precision and to increase stiffness so as to withstand the magnetic forces that may be several tens of newtons.

In order to optimize control over the vertical adjustment of the second forks 20, 20a, 20b, and 20c, the adjustment screws 24, 24a, 24b, and 24c may be arranged in pairs, the screws 24 and 24a for controlling the vertical adjustment of the second forks 20 and 20a emerging through the top end plate 43, while the screws 24b and 24c for controlling the vertical adjustment of the second forks 20b and 20c emerge through the bottom end plate 44. The control screws 24a and 24b merely pass through the bodies 27 and 27c respectively of the second end forks 20 and 20c via simple holes. The means for vertically adjusting the magnets of a set 60 may thus be compact. The adjustment system makes it possible to move the magnets in a vertical direction through less than 1 millimeter (mm).

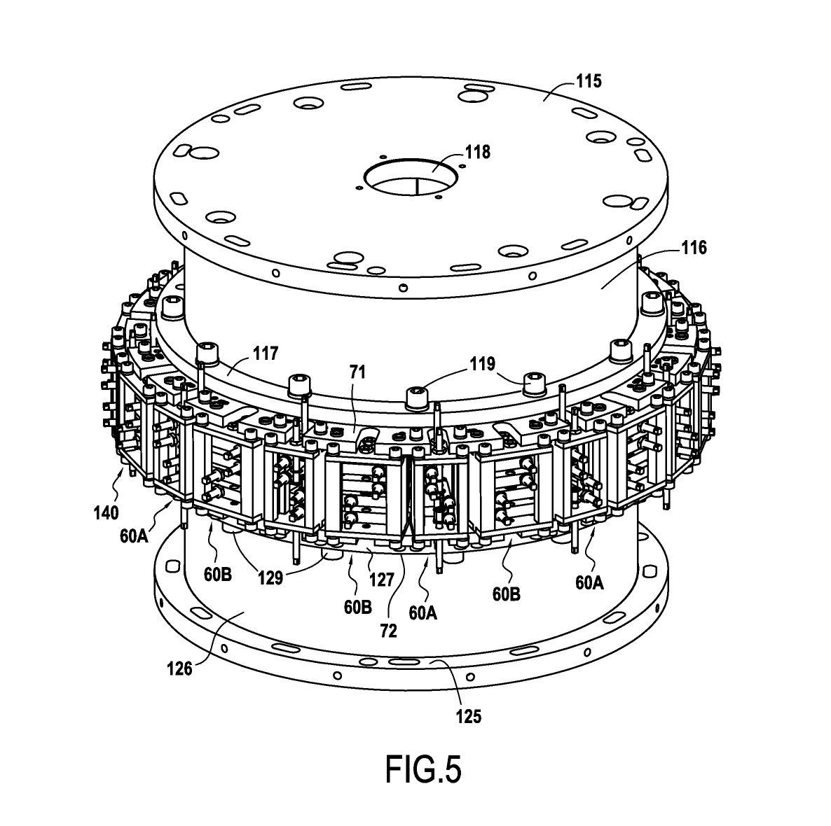

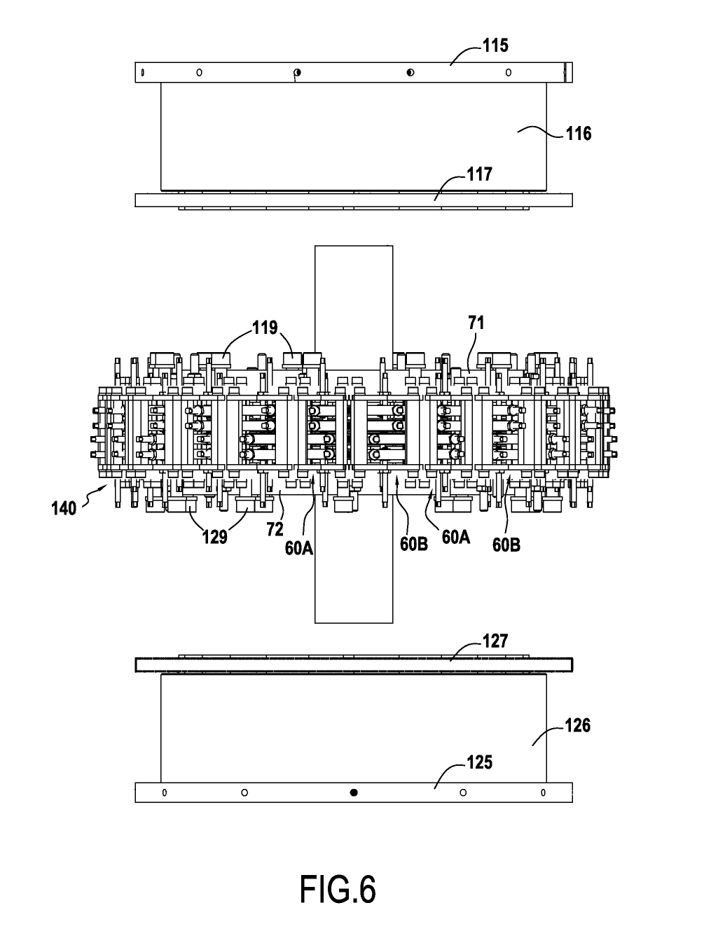

FIGS. 5 and 6 show embodiments in which the assembly 140 for holding and adjusting the individual magnets of a middle annular ring 130 having four superposed layers, such as that shown in FIGS. 10 and 11, comprises two series of support assemblies 60A and 60B that are arranged in alternating manner, each support assembly 60A or 60B comprising, for each group of four individual magnets defining a sector and in the manner shown in FIGS. 1 to 4: a stationary support device 40; and first and second forks associated with each individual magnet and provided with their radial and vertical adjustment screws. A top ring 71 and a bottom ring 72 hold the stationary supports 40 and the various support assemblies 60A, 60B in position.

FIGS. 5 and 6 show a magnetized structure and its holding and adjustment means as a whole. Such a magnetized structure makes it possible to obtain a homogeneous field at the magic angle and, for example, it may be rotated at a speed of 50 hertz (Hz). It makes it possible in particular to perform medical imaging on a small animal such as a mouse.

By way of example, a final magnetized structure may present outside dimensions of about 400 mm in height and about 400 mm in diameter, with a total weight of less than 300 kilograms (kg). Each of the outer rings 110, 120 and the central ring 130 (as described above with reference to FIGS. 10 and 11) is constituted by trapezoidal individual magnets having different characteristics that make it possible to obtain the desired homogeneous field at the magic angle.

The individual magnets of the outer rings 110 and 120 are positioned and adhesively bonded to one another, while the individual magnets of the central ring 130 are positioned and adjusted both radially and vertically in independent manner within the above-described blocks 60A, 60B.

Each of the outer rings 110, 120 and the central ring 130 is incorporated in its own mechanical support so as to enable the relative positions of the three rings 110, 120, and 130 to be mutually adjusted in all directions. Furthermore, the individual magnets of the central ring 130 are individually adjustable in the radial direction and in the vertical direction, as described above with reference to FIGS. 1 to 4.

The mechanical support of each outer ring 110, 120 is simple and comprises a cylinder 116, 126 having the same height as the ring and a plate 115, 125 enabling the final magnet to be closed at the magic angle. Each plate 115, 125 presents a central opening 118, 128 that makes it possible to perform magnetic corrections and NMR and field measurements. The individual magnets are assembled and bonded together and then positioned and adhesively bonded in the mechanical support. For example, for the bottom outer ring 120, there can be seen in FIGS. 8 and 9 individual magnets 121 and 122B that may be made in the manner shown in FIGS. 10 and 11 and arranged inside the space defined by the closure plate 125 and the cylinder 126. The cylinder 126 is fastened on the closure plate 125 and it is also fastened on the opposite side to a flange 127 fastened by fastener means 129 to the bottom ring 72 for holding in position the stationary supports of the various support assemblies 60A, 60B of the mechanical assembly 140 associated with the central ring 130.

The mechanical support for the top outer ring 110, visible in FIGS. 5 and 6 is analogous to the mechanical support for the bottom outer ring 120 as shown in FIGS. 8 and 9. In FIGS. 5 and 6, there can thus be seen the closure plate 115 provided with its central opening 118, the cylinder 116, the flange 117, and the means 119 for connection with the top ring 71 for holding in position the stationary supports of the various support assemblies 60A, 60B of the mechanical assembly 140 associated with the central ring 130.

Permanent magnets are very sensitive to temperature variations. The final magnetized structure, as shown in FIG. 5, is therefore associated with a thermal protection enclosure 150 in order to obtain best sensitivity and in order to optimize operation.

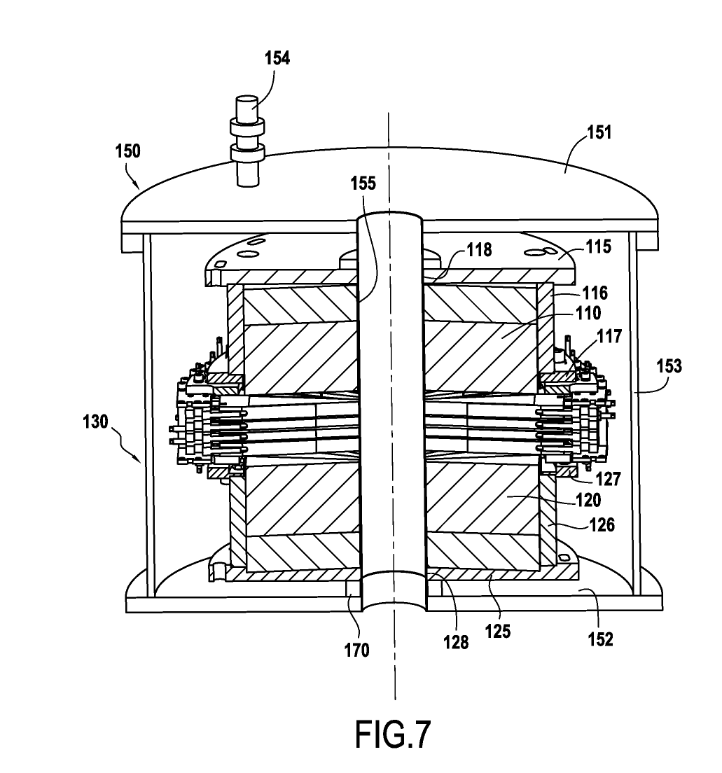

FIG. 7 shows an example of a thermal protection enclosure 150 which is simultaneously compact, inexpensive, and lightweight. Such an example of a thermal protection enclosure 150 comprises an outer cylinder 153 that serves to insulate the magnet from the outside, a bottom flange 152 forming a closure plate and providing the interface with a turntable or other support device, a top flange 151 providing closure and sealing with the addition of gaskets, and an inner cylinder 155 that passes through the central openings 118, 128 in the closure plate 115, 125 of the top and bottom outer rings 110, 120. The top flange 151 is also provided with two valves 154 enabling a vacuum to be established and maintained inside the thermal protection enclosure 150. Having two valves 154 present in an arrangement that is symmetrical about the main axis of the apparatus makes it possible to avoid any additional unbalance. The outer cylinder 153 and the inner cylinder 155 are advantageously welded to the bottom flange 152. Furthermore, an insulating part 170 may be interposed between the closure plate 125 of the bottom outer ring 120 and the bottom flange 152 of the thermal protection 150 so as to minimize heat transfer by conduction, in particular when the magnetized structure is driven in rotation on a turntable.

It should be observed that the invention is defined by the accompanying claims and is not limited to any of the various embodiments described above, which embodiments may be combined with one another.

What is claimed is:

1. A device for creating a main magnetic field of a spectroscopy or a magnetic resonant imaging system with individual permanent magnets being held and adjusted for the purpose of creating said magnetic field, said device being included in the spectroscopy or magnetic resonant imaging system, said system presenting a longitudinal axis relative to which a system of cylindrical coordinates can be defined with a longitudinal direction, a radial direction, and a tangential direction, each individual permanent magnet presenting main faces perpendicular to said longitudinal axis and lateral faces perpendicular to said main faces, wherein the device includes, for each individual permanent magnet, a first rigid fork of non-magnetic material that clamps the individual permanent magnet laterally in fixed manner, and a second rigid fork of non-magnetic material that engages said first fork by means of a slideway system oriented along said radial direction and that is provided with radial adjustment means for radially adjusting the first fork relative to a stationary support to which the second fork is attached, and wherein the second rigid fork is also provided with adjustment means for adjustment relative to the stationary support in a direction perpendicular to the main faces of said individual permanent magnet.

2. A device according to claim 1, wherein each individual permanent magnet is fastened in the first rigid fork by adhesive bonding.

3. A device according to claim 1, wherein said radial adjustment means comprise a threaded rod having one end engaged in a notch formed in a rear portion of said first fork.

4. A device according to claim 1, wherein said stationary support is provided with pegs for positioning the second forks associated with the individual permanent magnets that are arranged in a plurality of layers that are superposed along said longitudinal axis.

5. A device according to claim 1, wherein all of said stationary supports associated with the various individual permanent magnets are clamped between first and second holder rings.

6. A device according to claim 1, wherein said individual permanent magnets are arranged in at least first and second layers that are superposed along said longitudinal axis.

7. A device according to claim 6, wherein each stationary support is associated with a plurality of superposed individual permanent magnets and co-operates with guide grooves or splines formed in or on the second rigid forks respectively associated with said superposed individual permanent magnets.

8. A device according to claim 7, wherein each stationary support is associated with four superposed individual permanent magnets having their second rigid forks co-operating with adjustment means for adjustment relative to the stationary support in a direction perpendicular to the main faces of said individual permanent magnets, said adjustment means being distributed over two opposite sides of said stationary support.

9. A device according to claim 1, wherein the first and second rigid forks are made of 7075 aluminum alloy.

10. A device according to claim 1, wherein the individual permanent magnets are of a shape selected from rectangular blocks, cylinders, and sectors.

11. A magnetized structure applied to a nuclear magnetic resonance apparatus, the structure inducing, in a central zone of interest, a homogeneous magnetic field that is oriented along an axis at the magic angle relative to a longitudinal axis of the structure and comprising first and second magnetized rings arranged symmetrically relative to a plane that is perpendicular to said longitudinal axis and that contains said central zone of interest, and a middle annular magnetized structure interposed between the first and second magnetized rings, likewise arranged symmetrically about said plane, and subdivided into at least two slices along the longitudinal axis, the first and second magnetized rings and the various slices of the middle magnetized structure each being subdivided into individual permanent magnets of sector shape, wherein the sector-shaped individual permanent magnets of the various slices of the middle magnetized structure form parts of a device for creating a main magnetic field according to claim 1.

12. A magnetized structure according to claim 11, wherein the individual permanent magnets of the first and second magnetized rings are adhesively bonded to one another in fixed manner, while the magnetized structure includes longitudinal adjustment means between the first and second magnetized rings and the middle annular magnetized structure.

13. A method of creating a main magnetic field of a spectroscopy or a magnetic resonant imaging system with individual permanent magnets for creating said main magnetic field being held and adjusted, said spectroscopy or magnetic resonant imaging system presenting a longitudinal axis relative to which a system of cylindrical coordinates can be defined with a longitudinal direction, a radial direction, and a tangential direction, each individual permanent magnet presenting main faces perpendicular to said longitudinal axis and lateral faces perpendicular to said main faces, wherein for each individual permanent magnet it comprises the following steps:
placing a first rigid fork of non-magnetic material in fixed manner on each individual permanent magnet, the fork laterally clamping the individual permanent magnet in fixed manner;
for each individual permanent magnet, arranging a second rigid fork of non-magnetic material that engages said first fork via a slideway system oriented along said radial direction; and
radially adjusting the position of the first fork relative to a stationary support to which said second fork is attached; and
wherein it further comprises the step consisting in adjusting the position of the second fork relative to said stationary support in a direction perpendicular to the main faces of said individual permanent magnet.

14. A method according to claim 13, wherein a given stationary support is associated with a plurality of individual permanent magnets that are superposed along said longitudinal axis and fitted with said first and second rigid forks.
